(19) United States
(12) Patent Application Publication
(10) Pub. No.: US 2014/0312734 A1
(43) Pub. Date: Oct. 23, 2014

(54) VIBRATOR, OSCILLATOR, ELECTRONIC DEVICE, MOVING OBJECT, AND METHOD OF MANUFACTURING VIBRATOR

(71) Applicant: Seiko Epson Corporation, Tokyo (JP)

(72) Inventors: Shogo INABA, Shiojiri (JP); Osamu IWAMOTO, Chino (JP)

(73) Assignee: Seiko Epson Corporation, Tokyo (JP)

(21) Appl. No.: 14/254,330

(22) Filed: Apr. 16, 2014

(30) Foreign Application Priority Data
Apr. 18, 2013 (JP) 2013-087208

(51) Int. Cl. H02N 1/00; B81B 7/02

(52) U.S. Cl. CPC H02N 1/006; B81B 7/02
USPC 310/309; 29/846

(57) ABSTRACT

A MEMS vibrator includes a substrate, a lower electrode provided on a main surface of the substrate, a fixed portion provided on the main surface, and an upper electrode which is separated from the substrate and is supported by the fixed portion. The upper electrode is a vibrating body having a region overlapping the lower electrode when the substrate is seen in plan view, and includes a weight portion in a region provided with an antinode portion of vibration of the upper electrode as the vibrating body.

### BACKGROUND

1. Technical Field

The present invention relates to a vibrator, an oscillator, an electronic device, a moving object, and a method of manufacturing a vibrator.

2. Related Art

Generally, electro-mechanical system structures (for example, vibrators, filters, sensors, motors, and the like) are known which include a mechanically movable structure called a MEMS (Micro Electro Mechanical System) device formed using a semiconductor micromachining technique. Among the structures, a MEMS vibrator is easily manufactured by incorporating a semiconductor circuit, as compared with a vibrator and a resonator in which a quartz crystal or a dielectric has been used so far, and is advantageous to miniaturization and high functionality. Therefore, its applications are widespread.

As representative examples of the MEMS vibrator in the related art, a comb vibrator that vibrates in a direction parallel to the surface of a substrate provided with a vibrator and a beam vibrator that vibrates in the thickness direction of the substrate are known. The beam vibrator is a vibrator which is constituted by a fixed electrode formed on the substrate, a movable electrode disposed separately from the substrate, and the like. As the beam vibrator, a clamped-free beam, a clamped-clamped beam, a free-free beam and the like are known depending on a method of supporting the movable electrode.

JP-A-2010-162629 discloses a clamped-free beam type MEMS vibrator that includes a fixed electrode and a movable electrode, and drives (vibrates) the movable electrode using an electrostatic force generated by an AC voltage which is applied between both the electrodes. In such a clamped-free beam type vibrator, the drive frequency thereof is a natural vibration frequency of a vibrator, and the natural vibration frequency is determined by the material or shape (such as length or thickness) of a beam constituting the movable electrode. For example, the vibrator having a higher drive frequency can be obtained by further increasing the thickness of the beam, and further reducing the length of the beam. On the contrary, the vibrator having a lower drive frequency can be obtained by further reducing the thickness of the beam, and further increasing the length of the beam.

However, when a vibrator having a low drive frequency is formed by such a method, that is, when the length of a beam is, for example, increased, there is a problem that the size (occupation area) of the MEMS vibrator increases. In addition, there is also a problem that the strength of a cavity for sealing the MEMS vibrator in a reduced-pressure environment lowers due to an increase in the size of the MEMS vibrator, and that the durability or reliability of a device using the MEMS vibrator deteriorates.

In addition, when the thickness of the beam is further reduced, and the length of the beam is further increased, there is also a problem that the sticking of the beam is generated in the manufacturing process thereof, and that a sufficient manufacturing yield rate is not obtained. The term “sticking” herein refers to a phenomenon in which a fine structure (in this case, beam as the movable electrode) is attached to a substrate or other structures when a sacrificial layer is removed by etching in order to form a MEMS structure. In addition, when the length of the beam is further increased, the removal of the sacrificial layer by etching takes a long time, and thus there is also a problem of a reduction in the throughput of the manufacturing process being caused.

### SUMMARY

An advantage of some aspects of the invention is to solve at least a part of the problems described above, and the invention can be implemented as the following forms or application examples.

### Application Example 1

This application example is directed to a vibrator including: a substrate, a lower electrode which is provided on a main surface of the substrate, a fixed portion which is provided on the main surface, and an upper electrode which is separated from the substrate, and is supported by the fixed portion, wherein the upper electrode is a vibrating body having a region overlapping the lower electrode when the substrate is seen in plan view, and includes a weight portion in a region D1 provided with an antinode portion of vibration of the upper electrode as the vibrating body.

According to this application example, the vibrator includes the substrate, the lower electrode and the fixed portion which are provided on the main surface of the substrate, and the upper electrode which is separated from the substrate and is supported by the fixed portion, and the upper electrode is formed as a vibrating body having a region overlapping the lower electrode when the substrate is seen in plan view. Therefore, the vibrator is able to be formed as an electrostatic type beam vibrator that vibrates in the thickness direction of the substrate by an AC voltage applied to the lower electrode and the upper electrode.

In addition, according to this application example, the vibrator includes the weight portion in the region D1 provided with the antinode portion of vibration of the vibrating body (upper electrode). The weight portion is included in the region provided with the antinode portion of vibration, and thus it is possible to further lower the natural vibration frequency of the vibrator, as compared with a case where the weight portion is not included. That is, it is possible to further lower the drive frequency without increasing the length of the beam (upper electrode) of the vibrator. In other words, in a case of the vibrator having the same drive frequency, according to this application example, it is possible to further reduce the length of the beam (upper electrode) of the vibrator. As a result, it is possible to further reduce the size of the entire vibrator. In addition, the size of the vibrator is further reduced, and thus, for example, the vibration characteristics of the vibrating body are made more excellent. When a structure is formed in which the vibrator is received in a cavity in order to improve the reliability and environment resistance of the vibrator and is sealed in a reduced-pressure environment, it is possible to further reduce the size of the cavity. As a result, strength such as the stiffness of the cavity is further increased, and thus it is possible to further improve the reliability and environment resistance of the vibrator.

In addition, since the length of the beam (upper electrode) of the vibrator can be further reduced, it is possible to suppress a decrease in yield rate due to sticking in a manufacturing process of forming a vibrator as a MEMS structure. Specifically, in a manufacturing process of forming the separated upper electrode on the main surface of the substrate, even when surface tension or the like of an etching solution or a cleaning solution acts thereon, the upper electrode is not likely to remain attached onto the main surface of the substrate due to the short length of the upper electrode supported separately from the substrate by the fixed portion. That is, a sticking phenomenon is suppressed.

### Application Example 2

This application example is directed to the vibrator according to the application example described above, wherein in a thickness of the substrate, the weight portion includes a portion in which a thickness T1 of the region D1 of the upper electrode is larger than a thickness T2 of a region D2 provided with a node portion of vibration of the upper electrode as the vibrating body.

According to this application example, in the thickness of the substrate, the weight portion includes the portion in which the thickness T1 of the region D1 of the upper electrode is larger than the thickness T2 of the region D2 provided with the node portion of the vibration of the upper electrode. That is, the weight portion is formed by increasing (thickening) the dimensional shape of the region D1 of the upper electrode. Since the weight portion is not configured to use a material different from that of the upper electrode, it is possible to manufacture the weight portion more easily.

### Application Example 3

This application example is directed to the vibrator according to the application example described above, wherein the thickness T1 is larger than the thickness T2 from a main surface of the substrate in a direction toward the upper electrode.

According to this application example, the thickness T1 is larger than the thickness T2 from the main surface of the substrate in a direction toward the upper electrode. That is, the weight portion is formed on the upper side (side away from the main surface of the substrate) of the upper electrode. With such a configuration, it is possible to provide the weight portion without changing the distance of a gap between the lower electrode and the upper electrode. As a result, when the weight portion is formed as an electrostatic type beam vibrator that vibrates in the thickness direction of the substrate by an AC voltage applied to the lower electrode and the upper electrode, it is possible to further lower the drive frequency without influencing the movable range (amplitude) of the upper electrode, and without greatly changing the electrical characteristics thereof.

### Application Example 4

This application example is directed to the vibrator according to the application example described above, wherein the thickness T1 is larger than the thickness T2 from the upper electrode in a direction toward a main surface of the substrate.

According to this application example, the thickness T1 is larger than the thickness T2 from the upper electrode in a direction toward the main surface of the substrate. That is, the weight portion is formed on the lower side (side close to the main surface of the substrate) of the upper electrode. With such a configuration, it is possible to suppress a decrease in yield rate due to sticking in a manufacturing process. Specifically, in a process of forming the separated upper electrode on the main surface of the substrate, even when surface tension or the like of an etching solution or a cleaning solution acts thereon, the weight portion protruding in the main surface direction of the substrate is present in the region D1 of the upper electrode, and thus the upper electrode is not likely to remain attached onto the main surface of the substrate. That is, a sticking phenomenon is suppressed.

### Application Example 5

This application example is directed to the vibrator according to the application example described above, wherein the weight portion protrudes so as to taper from the upper electrode toward a direction of the substrate.

According to this application example, the weight portion formed on the lower side (side close to the main surface of the substrate) of the upper electrode protrudes so as to taper from the upper electrode toward the direction of the substrate. With such a configuration, it is possible to further effectively suppress a decrease in yield rate due to sticking, in a manufacturing process. Specifically, in a process of forming the separated upper electrode on the main surface of the substrate, even when surface tension or the like of an etching solution or a cleaning solution acts thereon, the weight portion protruding angularly in the main surface direction of the substrate is present in the region D1 of the upper electrode, and thus the upper electrode is not more likely to remain attached onto the main surface of the substrate. That is, a sticking phenomenon is further effectively suppressed.

### Application Example 6

This application example is directed to the vibrator according to the application example described above, wherein a thickness of the weight portion in a thickness direction of the substrate is equal to or less than a third of a gap between the lower electrode and the upper electrode.

According to this application example, the weight portion formed on the lower side (side close to the main surface of the substrate) of the upper electrode is configured such that the thickness of the weight portion in the thickness direction of the substrate is equal to or less than a third of the gap between the lower electrode and the upper electrode. Therefore, when the weight portion is formed as an electrostatic type beam vibrator that vibrates in the thickness direction of the substrate by an AC voltage applied to the lower electrode and the upper electrode, a gap between the lowermost surface of the weight portion and the lower electrode is a gap of at least equal to or more than two thirds of a gap except for the weight portion. Therefore, it is possible to further lower a drive frequency without having a great influence on the movable range (amplitude) of the upper electrode.

### Application Example 7

This application example is directed to the vibrator according to the application example described above, wherein the fixed portion supports the node portion of the vibration by a support portion extending from the fixed portion, and a structure constituted by the upper electrode and the weight portion is a rotational symmetry body of 2 n-fold symmetry having 2 n beams extending radially from the node portion of the vibration, in a natural number n.

According to this application example, the fixed portion supports the node portion of the vibration by the support portion extending from the fixed portion, and the structure constituted by the upper electrode and the weight portion is a rotational symmetry body of 2 n-fold symmetry having 2 n beams extending radially from the node portion of the vibration, in a natural number n. That is, even when the weight portion is configured to be included in the region D1 of the upper electrode, the shape inclusive of the weight portion is formed by a rotational symmetry body, and thus it is possible to maintain the balance of the vibration. For example, when the vibrator is formed as a beam vibrator that vibrates in the thickness direction of the substrate, the vibrations of the entire vibrating body counterbalance each other in the node portion of the vibration by reversing the phases of vibrations of beams adjacent to each other, and thus it is possible to suppress vibration leakage from the node portion of the vibration which is supported by the support portion. This is the same with a comb vibrator that vibrates in a direction parallel to the substrate surface, and thus it is possible to suppress vibration leakage from the node portion of the vibration which is supported by the support portion. As a result, even when the weight portion is provided, it is possible to suppress a decrease in vibration efficiency.

### Application Example 8

This application example is directed to a method of manufacturing a vibrator including: laminating a first electric conductor layer on a main surface of a substrate; forming the first electric conductor layer to form a lower electrode; laminating a first sacrificial layer so as to overlap the lower electrode; forming the first sacrificial layer to form a first opening in which at least a portion of the lower electrode is exposed; laminating a second electric conductor layer so as to overlap the first sacrificial layer and the first opening; forming the second electric conductor layer to form an upper electrode as a vibrating body having a region overlapping the lower electrode when the substrate is seen in plan view, a fixed portion having a region overlapping the first opening, and a support portion which extends from the fixed portion and is in connection with a position serving as a node portion of vibration of the upper electrode; laminating a second sacrificial layer so as to overlap the upper electrode, the fixed portion, and the support portion; forming the second sacrificial layer to form a second opening in which a region including a position serving as an antinode portion of vibration of the upper electrode is exposed; laminating a third electric conductor layer so as to overlap the second sacrificial layer and the second opening; forming the third electric conductor layer to form a weight portion at a position overlapping the second opening; and removing the first sacrificial layer and the second sacrificial layer by etching.

According to the method of manufacturing a vibrator in this application example, the vibrator is formed which includes the substrate, the lower electrode and the fixed portion which are provided on the main surface of the substrate, and the upper electrode which is separated from the substrate and is supported by the support portion extending from the fixed portion. In addition, the upper electrode is formed as a vibrating body having a region overlapping the lower electrode when the substrate is seen in plan view. Therefore, the vibrator obtained by the method of manufacturing a vibrator in this application example is able to be formed as an electrostatic type beam vibrator that vibrates in the thickness direction of the substrate by an AC voltage applied to the lower electrode and the upper electrode.

In addition, according to the method of manufacturing a vibrator of the application example, the vibrator includes the weight portion in the region D1 provided with the antinode portion of vibration of the vibrating body (upper electrode). The weight portion is included in the region provided with the antinode portion of vibration, and thus it is possible to further lower the natural vibration frequency of the vibrator, as compared with a case where the weight portion is not included. That is, it is possible to further lower the drive frequency without increasing the length of the beam (upper electrode) of the vibrator. In other words, in a case of the vibrator having the same drive frequency, according to this application example, it is possible to further reduce the length of the beam (upper electrode) of the vibrator. As a result, it is possible to further reduce the size of the entire vibrator. In addition, the size of the vibrator is further reduced, and thus, for example, the vibration characteristics of the vibrating body are made more excellent. When a structure is formed in which the vibrator is received in a cavity in order to improve the reliability and environment resistance of the vibrator and is sealed in a reduced-pressure environment, it is possible to further reduce the size of the cavity. As a result, strength such as the stiffness of the cavity is further increased, and thus it is possible to further improve the reliability and environment resistance of the vibrator.

In addition, since the length of the beam (upper electrode) of the vibrator can be further reduced, it is possible to suppress a decrease in yield rate due to sticking in a manufacturing process thereof. Specifically, in a process of forming the separated upper electrode on the main surface of the substrate, even when surface tension or the like of an etching solution or a cleaning solution acts thereon, the upper electrode is not likely to remain attached onto the main surface of the substrate due to the short length of the upper electrode supported separately from the substrate by the fixed portion. That is, a sticking phenomenon is suppressed.

### Application Example 9

This application example is directed to an oscillator including the vibrator according to the application example described above.

According to this application example, a smaller vibrator is utilized as the oscillator without an increase in size even at a lower frequency, and thus it is possible to provide a smaller oscillator at a frequency required in a lower-frequency region.

### Application Example 10

This application example is directed to an electronic device including the vibrator according to the application example described above.

According to this application example, a smaller vibrator is utilized as the electronic device without an increase in size even at a lower frequency, and thus it is possible to provide a smaller electronic device.

### Application Example 11

This application example is directed to a moving object including the vibrator according to the application example described above.

According to this application example, a smaller vibrator is utilized as the moving object without an increase in size even at a lower frequency, and thus it is possible to provide a moving object more excellent in space utility.

### BRIEF DESCRIPTION OF THE DRAWINGS

The invention will be described with reference to the accompanying drawings, wherein like numbers reference like elements.

FIG. 1A is a plan view of a vibrator according to Embodiment 1, and FIGS. 1B to 1D are cross-sectional views thereof.

FIG. 2 is a schematic diagram taken along cross-section B-B1-B2 of FIG. 1A.

FIGS. 3A to 3G are process diagrams illustrating a method of manufacturing a vibrator according to Embodiment 2 in order.

FIGS. 4A to 4G are process diagrams illustrating a method of manufacturing a vibrator according to Embodiment 3 in order.

FIG. 5 is a schematic diagram illustrating a configuration example of an oscillator including the vibrator according to Embodiment 1.

FIG. 6A is a perspective view illustrating a configuration of a mobile-type personal computer as an example of an electronic device, and FIG. 6B is a perspective view illustrating a configuration of a cellular phone as an example of an electronic device.

FIG. 7 is a perspective view illustrating a configuration of a digital still camera as an example of an electronic device.

FIG. 8 is a perspective view schematically illustrating an automobile as an example of a moving object.

FIG. 9 is a schematic cross-sectional view of a vibrator according to Modification Example 1.

FIG. 10A is a cross-sectional view schematically illustrating a variation example of an upper electrode as a vibrator according to Modification Example 2, FIGS. 10B and 10C are perspective view thereof, and FIG. 10D is a plan view thereof.

### DESCRIPTION OF EXEMPLARY EMBODIMENTS

Hereinafter, specific embodiments of the invention will be described with reference to the accompanying drawings. The following are embodiments of the invention, and the invention is not limited thereto. Meanwhile, the following drawings may be shown with different scales from those in reality in order to make the descriptions thereof easier to understand.

### Embodiment 1

First, a MEMS vibrator 100 as a vibrator according to Embodiment 1 will be described.

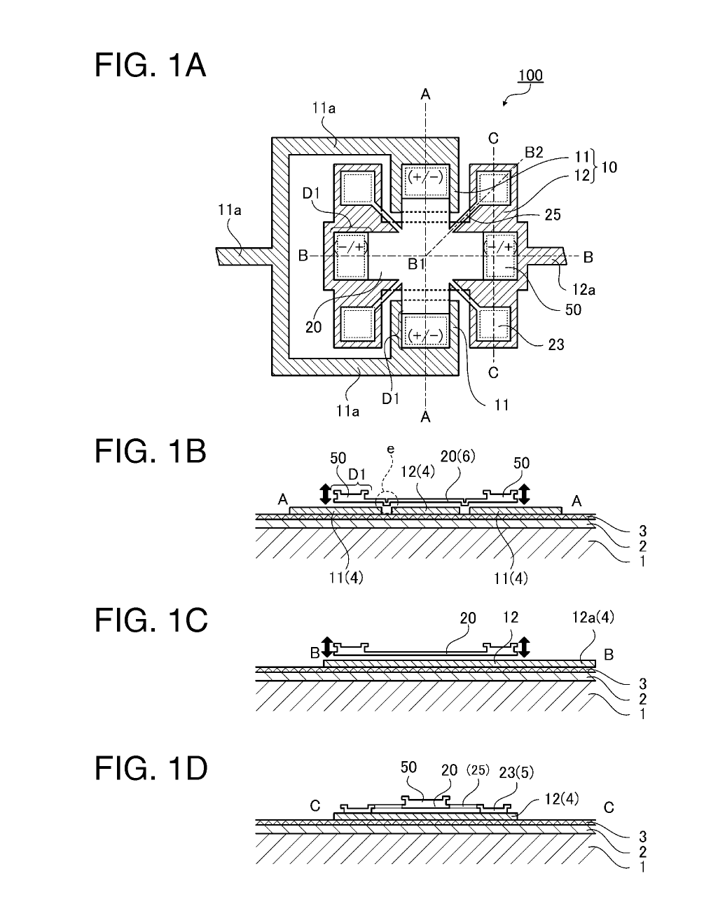

FIG. 1A is a plan view of the MEMS vibrator 100, FIG. 1B is a cross-sectional view taken along line A-A of FIG. 1A, FIG. 1C is a cross-sectional view taken along line B-B of FIG. 1A, and FIG. 1D is a cross-sectional view taken along line C-C of FIG. 1A.

The MEMS vibrator 100 is an electrostatic type beam vibrator which is provided with a lower electrode (fixed electrode) formed on a substrate and an upper electrode (movable electrode) formed separately from the substrate and the fixed electrode. The upper electrode is formed separately from the substrate and the lower electrode by a main surface of the substrate and a sacrificial layer laminated on the lower electrode being etched.

Meanwhile, the sacrificial layer is a layer which is formed once by an oxide film or the like, and is removed by etching after required layers are formed on the top and bottom thereof or in the vicinity thereof. The sacrificial layer is removed, so that required gaps or hollows are formed between layers on the top and bottom thereof or in the vicinity thereof, or required structures are separately formed.

The configuration of the MEMS vibrator 100 will be described below. A method of manufacturing the MEMS vibrator 100 will be described in an embodiment described later.

The MEMS vibrator 100 includes a substrate 1, a lower electrode 10 (first lower electrode 11 and second lower electrode 12) provided on the main surface of the substrate 1, a fixed portion 23 provided on the main surface, a support portion 25 extending from the fixed portion 23, and an upper electrode 20 separated from the substrate 1 and supported by the fixed portion 23 (specifically, support portion 25 extending from the fixed portion 23).

The upper electrode 20 is a vibrating body having a region overlapping the lower electrode 10 when the substrate 1 is seen in plan view, and includes a weight portion 50 in a region D1 provided with an antinode portion of the vibration of the upper electrode 20 as the vibrating body.

Meanwhile, the term “antinode portion of the vibration” herein means a portion having a maximum amplitude in a vibrator, and the term “node portion of the vibration” herein refers to a non-vibrating portion or a portion having a minimum vibration.

A silicon substrate is used in the substrate 1 as a preferred example. An oxide film 2 and a nitride film 3 are laminated on the substrate 1 in this order, and the lower electrode 10 (first lower electrode 11 and second lower electrode 12), the upper electrode 20, the fixed portion 23, the support portion 25, and the like are formed on the upper portion of the main surface (surface of the nitride film 3) of the substrate 1.

Meanwhile, here, a description is given in which a direction in which the oxide film 2 and nitride film 3 are laminated on the main surface of the substrate 1 in this order is set to an upward direction, in the thickness direction of the substrate 1.

The second lower electrode 12 in the lower electrode 10 is a fixed electrode which fixes the fixed portion 23 onto the substrate 1 and supplies a potential to the upper electrode 20 through the fixed portion 23 and the support portion 25, and is formed in an H shape, as shown in FIG. 1A, by a first electric conductor layer 4 laminated on the nitride film 3 being patterned using photolithography (inclusive of etching, the same hereinafter). In addition, the second lower electrode 12 is connected to an external circuit (not shown) by a wiring 12a.

The fixed portion 23 is provided at each of four ends of the H-shaped second lower electrode 12. The fixed portion 23 is formed by a second electric conductor layer 6 laminated through a sacrificial layer laminated on the upper layer of the first electric conductor layer 4 being patterned using photolithography. Meanwhile, a portion of the fixed portion 23 is laminated directly on the second lower electrode 12 by an opening provided in the sacrificial layer.

In the first electric conductor layer 4 and the second electric conductor layer 6, conductive polysilicon is used as a preferred example, but is not limited thereto.

The upper electrode 20 is a rotational symmetry body of 2 n-fold symmetry having 2 n beams extending radially from the central portion thereof where a natural number n=2. Specifically, as shown in FIG. 1A, the upper electrode is a movable electrode (vibrating body) showing a cross shape due to four beams extending from the central portion of the upper electrode 20, and is configured such that the central portion thereof is supported by four support portions 25 extending from four fixed portions 23 provided in the vicinity thereof. The upper electrode 20 is formed by the second electric conductor layer 6 laminated through the sacrificial layer laminated on the upper layer of the first electric conductor layer 4 being patterned using photolithography. That is, the four fixed portions 23, the four support portions 25, and the upper electrode 20 are formed integrally.

In addition, the H-shaped second lower electrode 12 and the cross-shaped upper electrode 20 are disposed overlapping with each other so that the central portions thereof are substantially coincident with each other when the substrate 1 is seen in plan view.

The first lower electrode 11 in the lower electrode 10 is a fixed electrode to which an AC voltage is applied between the first lower electrode and the upper electrode 20 overlapping the above electrode when the substrate 1 is seen in plan view, and is formed by the first electric conductor layer 4 laminated on the nitride film 3 being patterned using photolithography. The first lower electrode 11 is provided at two places so as to overlap two beams extending in a longitudinal direction (A-A direction) from the central portion of the upper electrode 20 when FIG. 1A is seen in front view, and is connected to an external circuit by the wiring 11a.

The first lower electrode 11 is formed by the first electric conductor layer 4 located on the same layer as the second lower electrode 12. Therefore, the first lower electrode 11 is required to be electrically isolated from the second lower electrode 12 as a fixed electrode that supplies a potential to the upper electrode 20, and the patterns thereof (first lower electrode 11 and second lower electrode 12) are separated from each other. The difference in level (unevenness) of a gap for separating these patterns from each other is transferred, as an uneven shape, to the upper electrode 20 which is formed by the second electric conductor layer 6 laminated through the sacrificial layer laminated on the upper layer of the first electric conductor layer 4. Specifically, as in an e portion shown in FIG. 1B, in the separated portion of the pattern, the uneven shape is formed on the upper electrode 20. The upper electrode 20 is formed as a rotational symmetry body of 2 n-fold symmetry having 2 n (n=2 in the present embodiment) beams extending radially from the central portion thereof, but is assumed to be rotationally symmetric without a difference between fine shapes due to the influence of such unevenness of the lower layer, dimensional variation in manufacturing, or the like.

In such a configuration, the MEMS vibrator 100 is formed as an electrostatic vibrator, and is configured such that tip regions of four beams of the upper electrode 20 are vibrated as the antinode of vibration by an AC voltage applied between the first lower electrode 11 and the upper electrode 20 from an external circuit through the wirings 11a and 12a. In FIG. 1A, the sign of (+/−) indicates portions vibrating in a vertical direction (thickness direction of the substrate 1) as the antinode of vibration, inclusive of a relation between the phases thereof. For example, when a + beam moves in an upward direction (direction away from the substrate 1), it is shown that the next beam moves in a − downward direction (direction approaching the substrate 1).

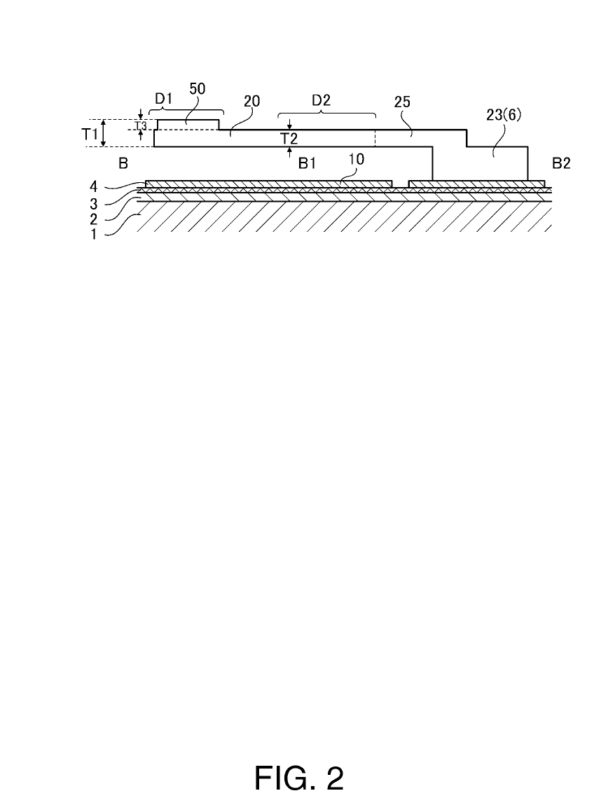

FIG. 2 is a cross-sectional view schematically illustrating cross-section B-B1-B2 of FIG. 1A.

As shown in FIG. 2, the upper electrode 20 includes the weight portion 50 in the region D1 provided with the antinode portions (tip regions of four beams of the upper electrode 20) of vibration as the vibrating body.

The weight portion 50 is formed by a portion (portion shown by thickness T3 in FIG. 2) in which in the thickness of the substrate 1, the thickness T1 of the region D1 of the upper electrode 20 is larger than the thickness T2 of a region D2 including a node portion of vibration of the upper electrode 20 as the vibrating body. In addition, the thickness T1 is larger than the thickness T2 in a direction from the main surface of the substrate 1 toward the upper electrode 20. That is, the weight portion 50 is provided on the upper electrode 20.

The same material as a material used in the upper electrode 20 is used in the weight portion 50. That is, conductive polysilicon is used therein. However, the material is not limited thereto, as is the case with the upper electrode 20.

Generally, when the density of a material constituting the vibrating body is set to p, the Young's modulus is set to E, the length of the beam of the vibrating body is set to L, and the thickness of the beam is set to T, the natural vibration frequency f of the beam vibrator can be represented by the following Expression (1).

$$f = \frac{1}{2 π} \sqrt{\frac{35 E}{33 ρ}} \times \frac{T}{{L}^{2}} \qquad ( 1 )$$

Therefore, when the lower natural vibration frequency f is desired to be obtained without changing the material constituting the vibrator or the film thickness thereof (thickness of the beam), it is necessary to further increase (make longer) the length L of the beam.

On the other hand, when the spring constant of the beam is set to k, and the mass of a mass point is set to M, the natural vibration frequency f of the beam vibrator of one mass system can be represented by the following Expression (2).

$$f = \frac{1}{2 π} \sqrt{\frac{k}{M}} \qquad ( 2 )$$

That is, when the lower natural vibration frequency f is desired to be obtained, the mass M of the tip portion of the beam may be further increased (made larger).

The weight portion 50 is a weight functioning in response to the mass M, and the natural vibration frequency f of the upper electrode 20 vibrating changes according to the size (thickness T3, or width) of the weight portion 50 and the position of a centroid within the region D1. Therefore, the size of the weight portion 50 and the position of a centroid are appropriately determined in accordance with a desired drive frequency.

As described above, according to the MEMS vibrator 100 of the present embodiment, the following effects can be obtained.

The MEMS vibrator 100 includes the weight portion 50 in the region D1 provided with the antinode portion of vibration of the vibrating body (upper electrode 20). The weight portion 50 is included in the region D1 provided with the antinode portion of vibration, and thus it is possible to further lower the natural vibration frequency f of the MEMS vibrator 100, as compared with a case where the weight portion 50 is not included. That is, it is possible to further lower the drive frequency without increasing the length of the beam (upper electrode 20) included in the MEMS vibrator 100. In other words, in a case of the vibrator having the same drive frequency, according to the present embodiment, it is possible to further reduce the length of the beam (upper electrode 20). As a result, it is possible to further reduce the size of the entire MEMS vibrator 100. In addition, the size of the MEMS vibrator 100 is further reduced, and thus, for example, the vibration characteristics of the vibrating body are made more excellent. When a structure is formed in which the vibrator is received in a cavity in order to improve the reliability and environment resistance of the vibrator and is sealed in a reduced-pressure environment, it is possible to further reduce the size of the cavity. As a result, strength such as the stiffness of the cavity is further increased, and thus it is possible to further improve the reliability and environment resistance of the vibrator.

In addition, since the length of the beam (upper electrode) included in the MEMS vibrator 100 can be further reduced, it is possible to suppress a decrease in yield rate due to sticking, for example, in a process of manufacturing the MEMS vibrator 100. Specifically, in a manufacturing process of forming the separated upper electrode 20 on the main surface of the substrate 1, even when surface tension or the like of an etching solution or a cleaning solution acts thereon, the upper electrode 20 is not likely to remain attached onto the main surface of the substrate 1 due to the short length of the upper electrode 20 supported separately from the substrate 1 by the fixed portion 23. That is, a sticking phenomenon is suppressed.

In addition, The weight portion 50 is formed by a portion in which in the thickness of the substrate 1, the thickness T1 of the region D1 of the upper electrode 20 is larger than the thickness T2 of a region D2 including a node portion of vibration of the upper electrode 20. That is, the weight portion 50 is formed by increasing (thickening) the dimensional shape of the region D1 of the upper electrode 20. Since the weight portion 50 is not configured to use a material different from that of the upper electrode 20, it is possible to form the weight portion more easily.

In addition, the thickness T1 is larger than the thickness T2 in a direction from the main surface of the substrate 1 toward the upper electrode 20. That is, the weight portion 50 is formed on the upper side (side away from the main surface of the substrate 1) of the upper electrode 20. With such a configuration, it is possible to provide the weight portion 50 without changing the distance of a gap between the lower electrode 10 and the upper electrode 20. As a result, when the weight portion is formed as an electrostatic type beam vibrator that vibrates in the thickness direction of the substrate 1 by an AC voltage applied to the lower electrode 10 and the upper electrode 20, it is possible to further lower the drive frequency f without influencing the movable range (amplitude) of the upper electrode 20, and without greatly changing the electrical characteristics thereof.

### Embodiment 2

Next, as Embodiment 2, a method of manufacturing the vibrator (MEMS vibrator 100) according to Embodiment 1 will be described. Meanwhile, in the following description, the same components as those of the above-mentioned embodiment are denoted by the same reference numerals and signs, and thus the description thereof will not repeated.

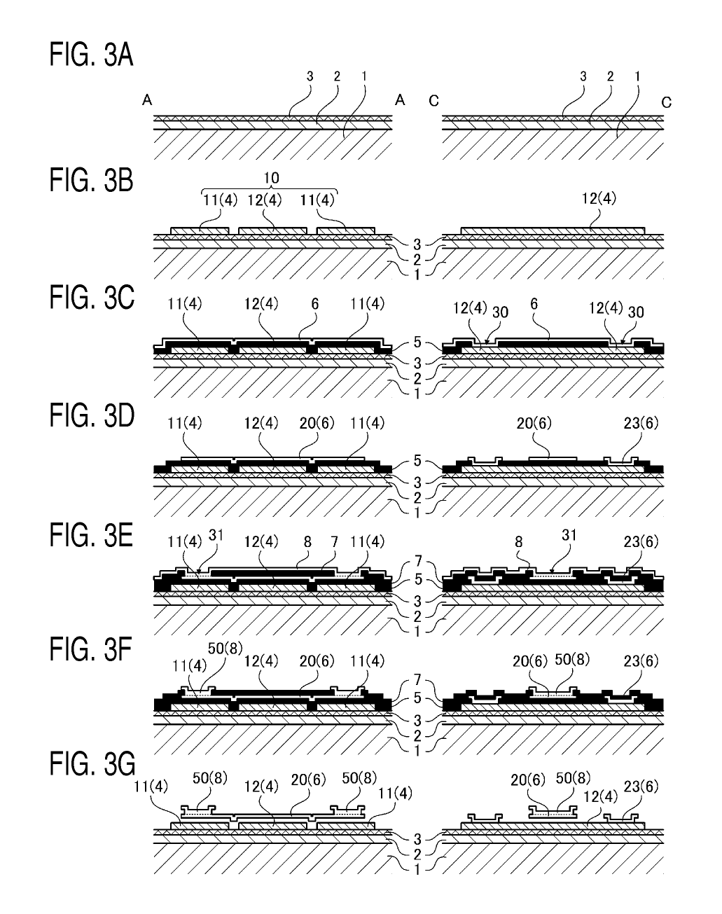

FIGS. 3A to 3G are process diagrams illustrating a method of manufacturing the MEMS vibrator 100 in order. The forms of the MEMS vibrator 100 in the respective processes are shown in the cross-sectional view taken along line A-A of FIG. 1A and the cross-sectional view taken along line C-C.

A method of manufacturing a vibrator according to the present embodiment includes: laminating a first electric conductor layer 4 on a main surface of a substrate 1; forming the first electric conductor layer 4 to form a lower electrode 10; laminating a first sacrificial layer 5 so as to overlap the lower electrode 10; forming the first sacrificial layer 5 to form a first opening 30 in which at least a portion of the lower electrode 10 is exposed; laminating a second electric conductor layer 6 so as to overlap the first sacrificial layer 5 and the first opening 30; forming the second electric conductor layer 6 to form an upper electrode 20 as a vibrating body having a region overlapping the lower electrode 10 when the substrate 1 is seen in plan view, a fixed portion 23 having a region overlapping the first opening 30, and a support portion 25 which extends from the fixed portion 23 and is in connection with a position serving as a node portion of vibration of the upper electrode 20 (FIG. 1A); laminating a second sacrificial layer 7 so as to overlap the upper electrode 20, the fixed portion 23, and the support portion 25; forming the second sacrificial layer 7 to form a second opening 31 in which a region including a position serving as an antinode portion of vibration of the upper electrode 20 is exposed; laminating a third electric conductor layer 8 so as to overlap the second sacrificial layer 7 and the second opening 31; forming the third electric conductor layer 8 to form a weight portion 50 at a position overlapping the second opening 31; and removing the first sacrificial layer 5 and the second sacrificial layer 7 by etching.

Hereinafter, a detailed description will be given with reference to FIGS. 3A to 3G.

FIG. 3A: the substrate 1 is prepared, and an oxide film 2 is laminated on the main surface. As a preferred example, the oxide film 2 is formed of general LOCOS (Local Oxidation of Silicon) oxide film as an element isolation layer of a semiconductor process, but may be an oxide film formed using, for example, an STI (Shallow Trench Isolation) method by the generation of a semiconductor process.

Next, a nitride film 3 as an insulating layer is laminated. As the nitride film 3, Si₃N₄ is formed by LPCVD (Low Pressure Chemical Vapor Deposition). The nitride film 3 shows resistance to a buffered hydrofluoric acid as an etching solution used when release etching is performed on a sacrificial layer, and functions as an etching stopper.

FIG. 3B: Next, the first electric conductor layer 4 is laminated on the nitride film 3. The first electric conductor layer 4 is a polysilicon layer constituting the lower electrode 10 (first lower electrode 11 and second lower electrode 12), the wirings 11a and 12a (see FIG. 1A), or the like, and is caused to have predetermined conductivity by performing ion implantation after the lamination. Next, the first electric conductor layer 4 is patterned using photolithography, to form the first lower electrode 11, the second lower electrode 12, and the wirings 11a and 12a.

FIG. 3C: Next, the first sacrificial layer 5 is laminated so as to overlap at least the lower electrode 10 and the wirings 11a and 12a. The first sacrificial layer 5 is a sacrificial layer for forming a gap between the first lower electrode 11, the second lower electrode 12 and the upper electrode 20 and separating the upper electrode 20, and is formed of a CVD (Chemical Vapor Deposition) oxide film.

Next, the first sacrificial layer 5 is patterned using photolithography, to form the first opening 30 in which a portion of the second lower electrode 12 is exposed. The first opening 30 forms a bonding region in which the fixed portion 23 is bonded and fixed to the second lower electrode 12. The bonding region is a region in which the upper electrode 20 is supported by the substrate 1 through the support portion 25, and thus opens an area by which required stiffness is obtained.

Next, the second electric conductor layer 6 is laminated so as to overlap the first sacrificial layer 5 and the first opening 30. The second electric conductor layer 6 is the same polysilicon layer as the first electric conductor layer 4.

FIG. 3D: Next, the second electric conductor layer 6 is patterned using photolithography, to form the support portion 25 which extends from the upper electrode 20, the fixed portion 23, and the fixed portion 23 and is in connection with a position serving as a node portion of vibration of the upper electrode 20 (FIG. 1A). As shown in FIG. 1A, the upper electrode 20 is an electrode having a region overlapping the first lower electrode 11 and the second lower electrode 12 when the substrate 1 is seen in plan view, and the shape of the upper electrode 20 is formed so that the 2 n beams extend radially from the central portion of the upper electrode 20 and become rotational symmetry bodies of 2 n-fold symmetry where a natural number n=2. In addition, the upper electrode is caused to have predetermined conductivity by performing ion implantation after the lamination.

FIG. 3E: Next, the second sacrificial layer 7 is laminated so as to overlap at least the upper electrode 20, the fixed portion 23, and the support portion 25, and is patterned using photolithography, to form the second opening 31 in which the region D1 (FIG. 2) including a position serving as an antinode portion of vibration of the upper electrode 20 is exposed. Next, the third electric conductor layer 8 is laminated so as to overlap the second sacrificial layer 7 and the second opening 31. The third electric conductor layer 8 is the same polysilicon layer as the first electric conductor layer 4 and the second electric conductor layer 6.

FIG. 3F: Next, the third electric conductor layer 8 is patterned using photolithography to form the weight portion 50 at a position overlapping the second opening 31.

FIG. 3G: Next, the substrate 1 is exposed to an etching solution (buffered hydrofluoric acid) and etching removal (release etching) is performed on the first sacrificial layer 5 and the second sacrificial layer 7, to form a gap between the first lower electrode 11, the second lower electrode 12 and the upper electrode 20 and separate the upper electrode 20.

In this manner, the MEMS vibrator 100 is formed.

Meanwhile, it is preferable that the MEMS vibrator 100 be installed in a hollow portion (cavity) sealed in a decompression state. For this reason, in the manufacturing of the MEMS vibrator 100, a sacrificial layer for forming the hollow portion, a sidewall portion surrounding the sacrificial layer, a sealing layer for forming a lid of the hollow portion, and the like are formed together, but the description thereof will not be given herein.

As described above, according to the method of manufacturing a vibrator in the present embodiment, the following effects can be obtained.

The MEMS vibrator 100 obtained by the manufacturing method according to the present embodiment includes the weight portion 50 in the region D1 provided with the antinode portion of vibration of the vibrating body (upper electrode 20). The weight portion 50 is included in the region D1 provided with the antinode portion of vibration, and thus it is possible to further lower the natural vibration frequency f of the MEMS vibrator 100, as compared with a case where the weight portion 50 is not included. That is, it is possible to further lower the drive frequency without increasing the length of the beam (upper electrode 20) included in the MEMS vibrator 100. In other words, in a case of the vibrator having the same drive frequency, according to the present embodiment, it is possible to further reduce the length of the beam (upper electrode 20). As a result, it is possible to further reduce the size of the entire MEMS vibrator 100. In addition, the size of the MEMS vibrator 100 is further reduced, and thus, for example, the vibration characteristics of the vibrating body are made more excellent. When a structure is formed in which the vibrator is received in a cavity in order to improve the reliability and environment resistance of the vibrator and is sealed in a reduced-pressure environment, it is possible to further reduce the size of the cavity. As a result, strength such as the stiffness of the cavity is further increased, and thus it is possible to further improve the reliability and environment resistance of the vibrator.

In addition, since the length of the beam (upper electrode) of the MEMS vibrator 100 can be further reduced, it is possible to suppress a decrease in yield rate due to sticking in a manufacturing process thereof. Specifically, in a process of forming the separated upper electrode 20 on the main surface of the substrate 1, even when surface tension or the like of an etching solution or a cleaning solution acts thereon, the upper electrode 20 is not likely to remain attached onto the main surface of the substrate 1 due to the short length of the upper electrode 20 supported separately from the substrate 1 by the fixed portion 23. That is, a sticking phenomenon is suppressed.

Meanwhile, in the above-mentioned embodiment, the method of providing the weight portion 50 on the upper portion (thickness direction of the substrate 1) of the upper electrode 20 has been described as a method of laminating the third electric conductor layer 8 on the upper electrode 20 and performing patterning, but is not limited to this method. For example, a method may be used in which the upper surface of the upper electrode 20 except for the weight portion 50 is removed by half etching or the like so that the upper electrode 20 is formed once in the second electric conductor layer 6 having a thickness required for the weight portion 50 and the weight portion 50 is next formed in the region D1.

### Embodiment 3

Next, as Embodiment 3, a method of manufacturing the vibrator (MEMS vibrator 100) according to Embodiment 1 will be described. Meanwhile, in the following description, the same components as those of the above-mentioned embodiment are denoted by the same reference numerals and signs, and thus the description thereof will not repeated.

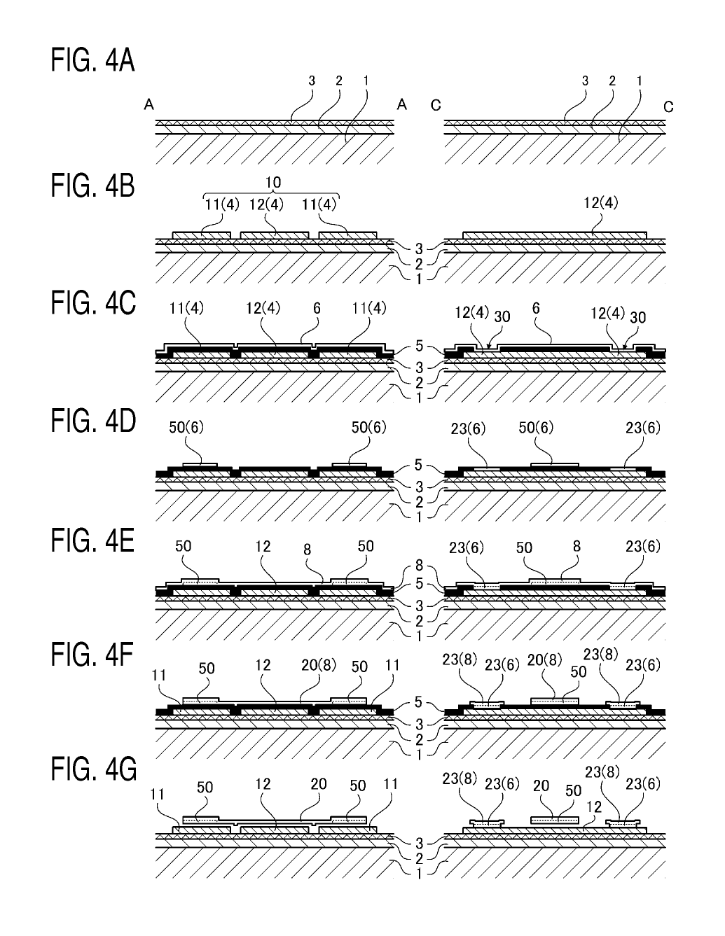

FIGS. 4A to 4G are process diagrams illustrating a method of manufacturing the MEMS vibrator 100 in order. The forms of the MEMS vibrator 100 in the respective processes are shown in the cross-sectional view taken along line A-A of FIG. 1A and the cross-sectional view taken along line C-C.

In a manufacturing method according to Embodiment 2, a method of providing the weight portion 50 on the upper electrode 20 which is first formed is described, but is not limited thereto. In the method of manufacturing a vibrator according to Embodiment 3, the weight portion 50 is first formed, and the upper electrode 20 is formed thereon.

Hereinafter, a detailed description will be given with reference to FIGS. 4A to 4G.

FIGS. 4A to 4C: processes proceed until a process of laminating the second electric conductor layer 6 using the same processes as those of FIGS. 3A to 3C. In addition, the second electric conductor layer 6 is caused to have predetermined conductivity by performing ion implantation after the lamination thereof.

FIG. 4D: Next, the second electric conductor layer 6 is patterned using photolithography, to form first layers of the weight portion 50 and the fixed portion 23.

FIG. 4E: Next, the third electric conductor layer 8 is laminated so as to overlap at least the weight portion 50 and the fixed portion 23 (the first layer of the fixed portion 23). The third electric conductor layer 8 is the same polysilicon layer as the first electric conductor layer 4 and the second electric conductor layer 6.

FIG. 4F: Next, the third electric conductor layer 8 is patterned using photolithography, to form the upper electrode 20, the second layer of the fixed portion 23, and the support portion 25 which extends from the fixed portion 23 and is in connection with a position serving as a node portion of vibration of the upper electrode 20 (FIG. 1A). As shown in FIG. 1A, the upper electrode 20 is an electrode having a region overlapping the first lower electrode 11 and the second lower electrode 12 when the substrate 1 is seen in plan view, and the shape of the upper electrode 20 is formed so that the 2 n beams extend radially from the central portion of the upper electrode 20 and become rotational symmetry bodies of 2 n-fold symmetry where a natural number n=2. In addition, the upper electrode is caused to have predetermined conductivity by performing ion implantation after the lamination.

FIG. 4G: Next, the substrate 1 is exposed to an etching solution (buffered hydrofluoric acid) and etching removal (release etching) is performed on the first sacrificial layer 5 and the second sacrificial layer 7, to form a gap between the first lower electrode 11, the second lower electrode 12 and the upper electrode 20 and separate the upper electrode 20.

In this manner, the MEMS vibrator 100 is formed.

Meanwhile, in the present embodiment, as is the case with Embodiment 2, the description of the manufacturing method inclusive of the cavity will not be given.

As described above, according to the method of manufacturing a vibrator in the present embodiment, the following effects can be further obtained in addition to the effects of Embodiment 2.

Since the lamination and patterning of the second sacrificial layer 7 can be omitted by using a method of first forming the weight portion 50 and forming the upper electrode 20 thereon, it is possible to manufacture the MEMS vibrator 100 more easily.

### Oscillator

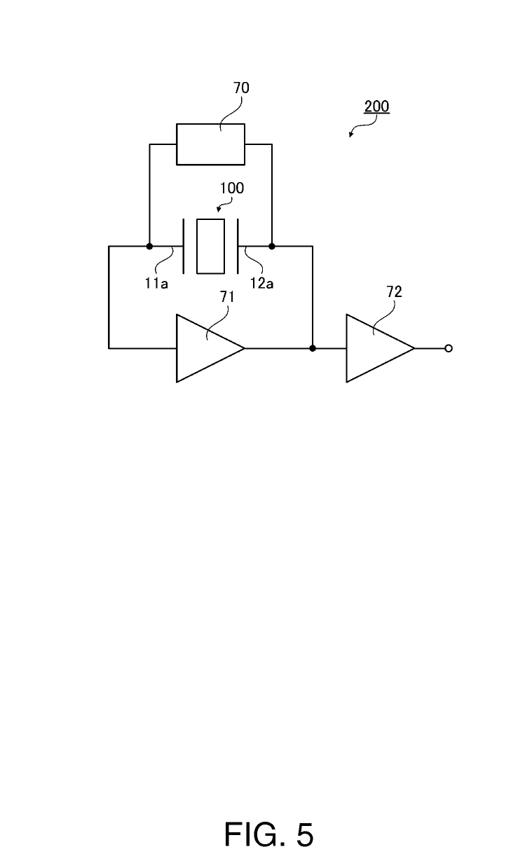

Next, an oscillator 200 to which the MEMS vibrator 100 as an oscillator according to an embodiment of the invention is applied will be described with reference to FIG. 5.

FIG. 5 is a schematic diagram illustrating a configuration example of an oscillator including the MEMS vibrator 100 according to an embodiment of the invention. The oscillator 200 is constituted by the MEMS vibrator 100, a bias circuit 70, amplifiers 71 and 72, and the like.

The bias circuit is a circuit which is connected to the wirings 11a and 12a of the MEMS vibrator 100, and applies an AC voltage having a predetermined potential biased to the MEMS vibrator 100.

The amplifier 71 is a feedback amplifier which is connected to the wirings 11a and 12a of the MEMS vibrator 100 in parallel to the bias circuit. The MEMS vibrator 100 is formed as an oscillator by performing feedback amplification.

The amplifier 72 is a buffer amplifier that outputs an oscillation waveform.

According to the present embodiment, a smaller vibrator is utilized as an oscillator without an increase in size even at a lower frequency, and thus it is possible to provide a smaller oscillator at a frequency required in a lower-frequency region.

### Electronic Device

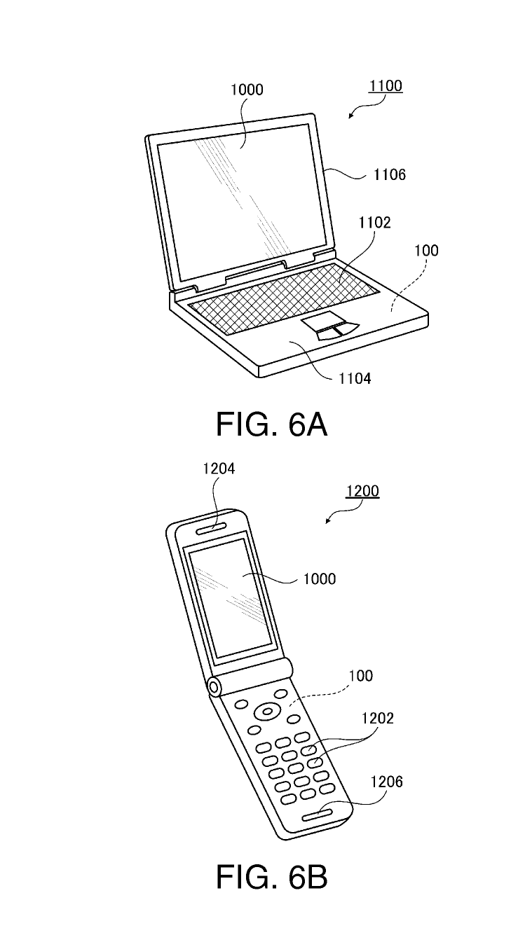

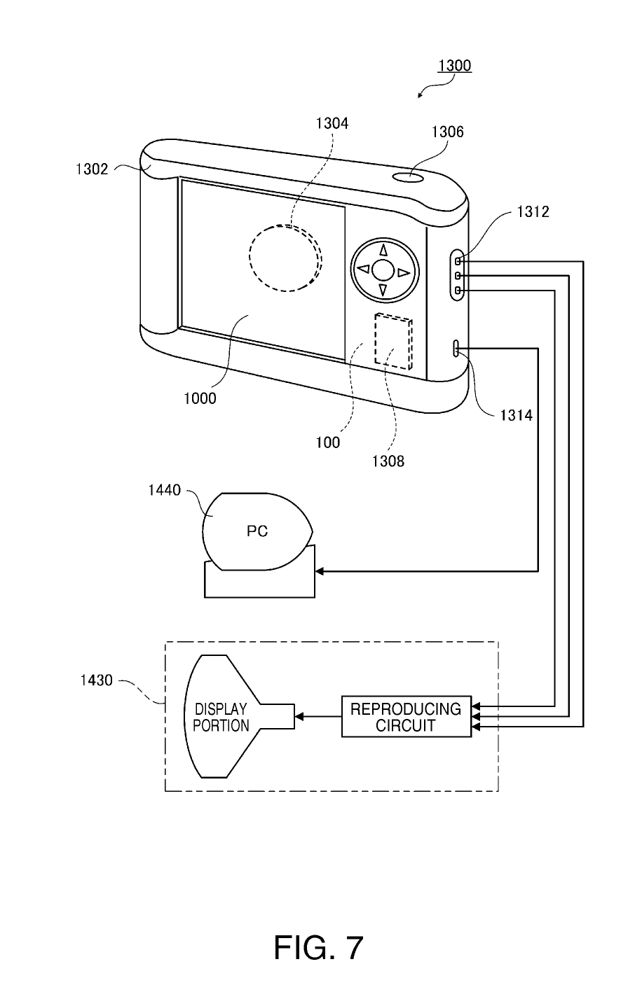

Next, electronic devices to which the MEMS vibrator 100 as electronic components according to an embodiment of the invention is applied will be described with reference to FIGS. 6A and 6B and FIG. 7.

FIG. 6A is a perspective view illustrating an outline of a configuration of a mobile-type (or notebook-type) personal computer as an electronic device including the electronic component according to the embodiment of the invention. In the drawing, a personal computer 1100 is constituted by amain body 1104 including a keyboard 1102 and a display unit 1106 including a display portion 1000, and the display unit 1106 is rotatably supported with respect to the main body 1104 through a hinge structure. Such a personal computer 1100 has the MEMS vibrator 100 as an electronic component built-in which functions as a filter, a resonator, a reference clock or the like.

FIG. 6B is a perspective view illustrating an outline of a configuration of a cellular phone (also including PHS) as an electronic device including the electronic component according to the embodiment of the invention. In the drawing, a cellular phone 1200 includes a plurality of operation buttons 1202, an ear piece 1204 and a mouth piece 1206, and a display portion 1000 is disposed between the operation buttons 1202 and the ear piece 1204. Such a cellular phone 1200 has the MEMS vibrator 100 built-in which is used as an electronic component (timing device) functioning as a filter, a resonator, an angular velocity sensor, and the like.

FIG. 7 is a perspective view illustrating an outline of a configuration of a digital still camera as an electronic device including the electronic component according to the embodiment of the invention. Meanwhile, in the drawing, the connection with an external device is also shown simply. A digital still camera 1300 generates an imaging signal (image signal) by photoelectrically converting a light image of a subject using an imaging device such as a CCD (Charge Coupled Device).

A display portion 1000 is provided on the rear of a case (body) 1302 in the digital still camera 1300, and is configured to perform a display on the basis of an imaging signal of a CCD. The display portion 1000 functions as a viewfinder for displaying a subject as an electronic image. In addition, a light-receiving unit 1304 including an optical lens (imaging optical system), a CCD and the like is provided on the front side (back side in the drawing) of the case 1302.

When a photographer confirms a subject image displayed on the display portion 1000 and pushes a shutter button 1306, an imaging signal of the CCD at that point in time is transmitted and stored to and in a memory 1308. In addition, in the digital still camera 1300, a video signal output terminal 1312 and an input and output terminal 1314 for data communication are provided on the lateral side of the case 1302. As shown in the drawing, a TV monitor 1430 is connected to the video signal output terminal 1312 and a personal computer 1440 is connected to the input and output terminal 1314 for data communication, respectively as necessary. Further, the imaging signal stored in the memory 1308 is output to the TV monitor 1430 or the personal computer 1440 by a predetermined operation. Such a digital still camera 1300 has the MEMS vibrator 100 built-in which is used as an electronic component functioning as a filter, a resonator, an angular velocity sensor, and the like.

As described above, a smaller vibrator is utilized as an electronic device without an increase in size even at a lower frequency, and thus it is possible to provide a smaller electronic device.

Meanwhile, in addition to the personal computer (mobile-type personal computer) of FIG. 6A, the cellular phone of FIG. 6B, and the digital still camera of FIG. 7, the MEMS vibrator 100 as the electronic components according to the embodiment of the invention can be applied to electronic devices such as, for example, an ink jet ejecting apparatus (for example, ink jet printer), a laptop personal computer, a television, a video camera, a car navigation device, a pager, an electronic notebook (also including a communication function), an electronic dictionary, an electronic calculator, an electronic game console, a workstation, a TV phone, a security TV monitor, electronic binoculars, a POS terminal, medical instrument (for example, electronic thermometer, sphygmomanometer, blood glucose monitoring system, electrocardiogram measurement device, ultrasound diagnostic device, and electronic endoscope), a fish finder, various types of measuring apparatus, meters and gauges (for example, meters and gauges of a vehicle, an aircraft, and a vessel), and a flight simulator.

### Moving Object

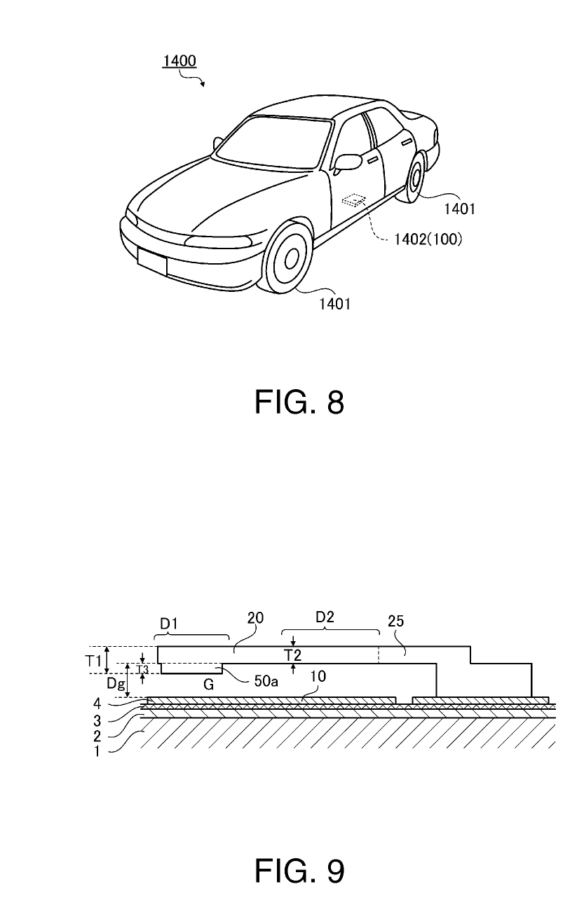

Next, a moving object to which the MEMS vibrator 100 as the vibrator according to an embodiment of the invention is applied will be described with reference to FIG. 8.

FIG. 8 is a perspective view schematically illustrating an automobile 1400 as a moving object including the MEMS vibrator 100. A gyro sensor including the MEMS vibrator 100 according to the invention is mounted to the automobile 1400. For example, as shown in the drawing, an electronic control unit 1402 having the gyro sensor built-in which controls wheels 1401 is mounted to the automobile 1400 as a moving object. In addition, as other examples, the MEMS vibrator 100 can be applied widely to electronic control units (ECUs) such as a keyless entry, an immobilizer, a car navigation system, a car air conditioner, an antilock brake system (ABS), an air bag, a tire pressure monitoring system (TPMS), engine control, a battery monitor of a hybrid automobile or an electric automobile, and a car-body posture control system.

As described above, a smaller vibrator is utilized as a moving object without an increase in size even at a lower frequency, and thus it is possible to provide a moving object more excellent in space utility.

Meanwhile, the invention is not limited to the above-mentioned embodiment, but various changes, modifications, and the like can be added to the above-mentioned embodiment. Modification examples will be described below. Here, the same components as those of the above-mentioned embodiment are denoted by the same reference numerals and signs, and thus the description thereof will not repeated.

### Modification Example 1

FIG. 9 is a cross-sectional view schematically illustrating a cross-section (cross-section located at the same position as that of FIG. 2) of a vibrator according to Modification Example 1.

In Embodiment 1, as shown in FIG. 2, a description has been given in which the weight portion 50 is formed by a portion (portion shown by thickness T3) in which the thickness T1 of the region D1 of the upper electrode 20 is larger than the thickness T2 of the region D2 of the upper electrode 20, and the portion (that is, weight portion 50) of the thickness T3 is provided on the upper electrode 20. On the other hand, in Modification Example 1, a weight portion 50a is included, and a portion having the thickness T3 which constitutes the weight portion 50a is provided below the upper electrode 20. Modification Example 1 is the same as the Embodiment 1, except for this point.

The weight portion 50a is provided so as to protrude from the lower surface of the upper electrode 20 in a direction toward the lower electrode 10, in a gap G between the upper electrode 20 and the lower electrode 10. In addition, the size Dg of a gap between the lower surface of the upper electrode 20 and the upper surface of the lower electrode 10, and the thickness T3 are established so as to satisfy the relation of T3≦Dg/3. That is, the thickness T3 of the weight portion 50a in the thickness direction of the substrate 1 is equal to or less than a third of the size Dg of a gap between the lower electrode 10 and the upper electrode 20.

According to the present modification example, when the weight portion is formed as an electrostatic type beam vibrator that vibrates in the thickness direction of the substrate 1 by an AC voltage applied to the lower electrode 10 and the upper electrode 20, a gap between the lowermost surface of the weight portion 50a and the lower electrode 10 has a gap of at least equal to or more than two thirds of a gap except for the weight portion 50a. Therefore, it is possible to further lower a drive frequency without having a great influence on the movable range (amplitude) of the upper electrode 20.

### Modification Example 2

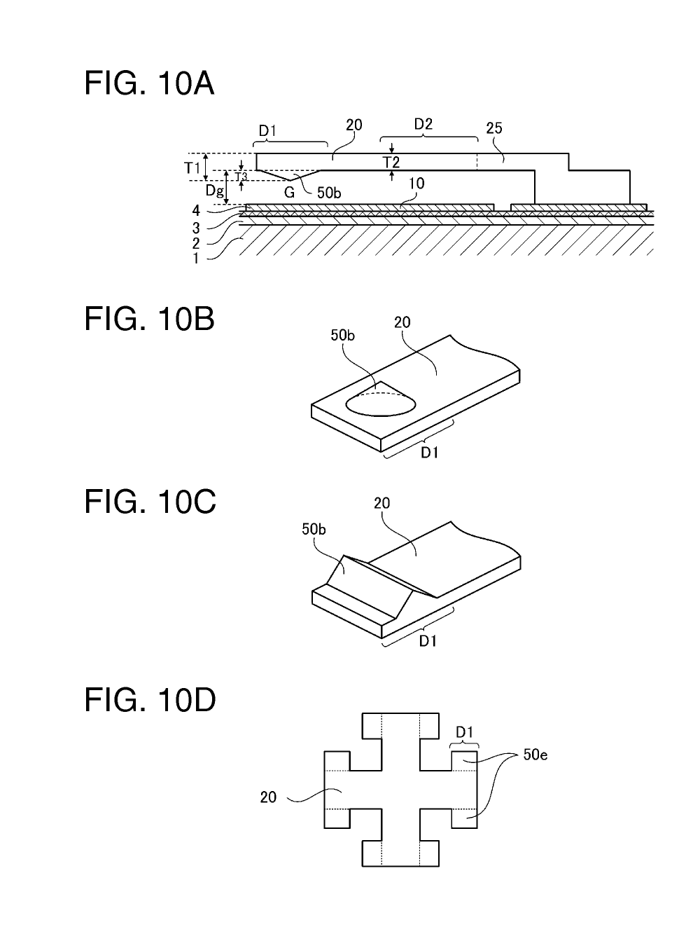

FIG. 10A is a cross-sectional view schematically illustrating a variation example of the upper electrode 20 as a vibrator according to Modification Example 2.

The vibrator according to Modification Example 2 includes a weight portion 50b, provided on the lower surface of the upper electrode 20, which protrudes angularly in a downward direction. Modification Example 2 is the same as Modification Example 1, except for this point.

The weight portion 50b is provided so as to protrude from the lower surface of the upper electrode 20 in the direction toward the lower electrode 10, in a gap G between the upper electrode 20 and the lower electrode 10. In addition, the shape of the weight portion 50b protrudes so as to taper from the upper electrode 20 toward the direction of the substrate 1.

FIGS. 10B and 10C are perspective views illustrating an example of the specific shape of the weight portion 50b. Each of the perspective views is a diagram when seen from the lower surface of the upper electrode 20.

The weight portion 50b may have, for example, a shape showing a conical form shown in FIG. 10B. Alternatively, as shown in FIG. 10C, the weight portion may have a shape showing a triangular prism extending in a transverse direction (transverse direction intersecting the extending direction of the upper electrode 20).

According to the present modification example, the weight portion 50b formed on the lower side (side close to the main surface of the substrate 1) of the upper electrode 20 protrudes so as to taper from the upper electrode 20 toward the direction of the substrate 1. With such a configuration, it is possible to further effectively suppress a decrease in yield rate due to sticking, in a manufacturing process. Specifically, in a manufacturing process of forming the separated upper electrode 20 on the main surface of the substrate 1, even when surface tension or the like of an etching solution or a cleaning solution acts thereon, the weight portion 50b protruding angularly in the main surface direction of the substrate 1 is present in the region D1 of the upper electrode 20, and thus the upper electrode 20 is not likely to remain attached onto the main surface of the substrate 1. That is, a sticking phenomenon is further effectively suppressed.

### Modification Example 3

FIG. 10D is a plan view schematically illustrating a variation example of the upper electrode 20 as a vibrator according to Modification Example 3.

In Embodiment 1, as shown in FIG. 1A, a description has been given in which the upper electrode 20 is a movable electrode showing a cross shape due to four beams extending from the central portion of the upper electrode 20, and the weight portion 50 is provided on the upper portion (that is, direction of the lamination on the upper electrode 20 in the thickness direction of the substrate 1) of the upper electrode 20, in the region D1. On the other hand, the upper electrode 20 included in the vibrator of the present modification example includes a weight portion 50e, and the weight portion 50e is included in the same surface on which the upper electrode 20 extends in the region D1.

In other words, the four beams extending from the central portion of the upper electrode 20 is not limited to a rectangular beam as shown in FIG. 1A, but, for example, as shown in FIG. 10D, each of the beams (upper electrode 20) may have a shape including the weight portion 50e so as to be formed in a hammer shape when the upper electrode 20 is seen in plan view, in the region D1.

As in the present modification example, the weight portion 50e is included in the same surface on which the upper electrode 20 extends, and thus it is possible to cope with such a configuration just by changing the patterning shape of the upper electrode 20, without increasing the number of processes for forming the weight portion 50 newly. Therefore, it is possible to manufacture the weight portion more easily.

The entire disclosure of Japanese Patent Application No. 2013-087208, filed Apr. 18, 2013 is expressly incorporated by reference herein.

What is claimed is:

1. A vibrator comprising:
a substrate;
a lower electrode which is disposed on the substrate;
a fixed portion which is disposed on the substrate; and
an upper electrode which is separated from the substrate, and is supported by the fixed portion,
wherein the upper electrode is a vibrating body having a region overlapping the lower electrode when the substrate is seen in plan view, and includes a weight portion in a region D1 provided with an antinode portion of vibration of the upper electrode as the vibrating body.

2. The vibrator according to claim 1, wherein the weight portion includes a portion in which a thickness T1 of the region D1 is larger than a thickness T2 of a region D2 provided with a node portion of vibration of the upper electrode as the vibrating body.

3. The vibrator according to claim 2, wherein the thickness T1 is larger than the thickness T2 from a main surface of the substrate in a direction toward the upper electrode.

4. The vibrator according to claim 2, wherein the thickness T1 is larger than the thickness T2 from the upper electrode in a direction toward amain surface of the substrate.

5. The vibrator according to claim 4, wherein the weight portion protrudes so as to taper from the upper electrode toward a direction of the substrate.

6. The vibrator according to claim 4, wherein a thickness of the weight portion in a thickness direction of the substrate is equal to or less than a third of a gap between the lower electrode and the upper electrode.

7. The vibrator according to claim 2, wherein the fixed portion supports the node portion of the vibration by a support portion extending from the fixed portion, and
a structure constituted by the upper electrode and the weight portion is a rotational symmetry body of 2 n-fold symmetry having 2 n beams extending radially from the node portion of the vibration, in a natural number n.

8. A method of manufacturing a vibrator, comprising:
laminating a first electric conductor layer on a main surface of a substrate;
forming the first electric conductor layer to form a lower electrode;
laminating a first sacrificial layer so as to overlap the lower electrode;
forming the first sacrificial layer to form a first opening in which at least a portion of the lower electrode is exposed;
laminating a second electric conductor layer so as to overlap the first sacrificial layer and the first opening;
forming the second electric conductor layer to form an upper electrode as a vibrating body having a region overlapping the lower electrode when the substrate is seen in plan view, a fixed portion having a region overlapping the first opening, and a support portion which extends from the fixed portion and is in connection with a position serving as a node portion of vibration of the upper electrode;
laminating a second sacrificial layer so as to overlap the upper electrode, the fixed portion, and the support portion;
forming the second sacrificial layer to form a second opening in which a region including a position serving as an antinode portion of vibration of the upper electrode is exposed;
laminating a third electric conductor layer so as to overlap the second sacrificial layer and the second opening;
forming the third electric conductor layer to form a weight portion at a position overlapping the second opening; and
removing the first sacrificial layer and the second sacrificial layer by etching.

9. An oscillator comprising the vibrator according to claim 1.

10. An electronic device comprising a vibrator according to claim 1.

11. A moving object comprising a vibrator according to claim 1.
